(19) United States
(12) Patent Application Publication
(10) Pub. No.: US 2026/0190256 A1
(43) Pub. Date: Jul. 2, 2026

(54) FLEXIBLE CURVED DISPLAY APPARATUS

(71) Applicant: LG Display Co., Ltd., Seoul (KR)

(72) Inventor: Sung Been PARK, Paju-si (KR)

(73) Assignee: LG Display Co., Ltd., Seoul (KR)

(21) Appl. No.: 19/345,848

(22) Filed: Sep. 30, 2025

(30) Foreign Application Priority Data
Dec. 31, 2024 (KR) 10-2024-0202460

(51) Int. Cl. H05K 5/02; G06F 3/041; H10K 59/80; H10K 102/00

(52) U.S. Cl. CPC H05K 5/0226; H10K 59/80; G06F 3/0412; H10K 2102/311

(57) ABSTRACT

A flexible curved display apparatus includes a display part displaying an image, and a curvature-forming member having an inner side joined to a rear surface of the display part to bend the display part, and the curvature-forming member includes a plurality of body parts disposed in a row, a hinge member penetrating two adjacent body parts to connect the two adjacent body parts and forming a rotation axis of each body part of the two adjacent body parts, and a torsion spring whose both ends push the two adjacent body parts in a first direction in which the display part is located to offset a restoring force of the display part being bent.

This application claims the benefit of Korean Patent Application No. 10-2024-0202460, filed on Dec. 31, 2024, which is hereby incorporated by reference as if fully set forth herein.

### BACKGROUND

### Technical Field

The present disclosure relates to a display apparatus, and more specifically, to a flexible curved display apparatus with a curvature which is capable of being changed in various ways.

### Discussion of the Related Art

Image display apparatuses that display various types of information on screens are core technology of the information and communication era, and are developing into thinner, lighter, more portable, and higher performance display apparatuses. Accordingly, display apparatuses that can be manufactured in a lightweight and thin structure are in the spotlight.

Specific examples of such display apparatuses include a liquid crystal display (LCD) apparatus, a quantum dot display (QD) apparatus, a field emission display (FED) apparatus, and an organic light emitting diode (OLED) display apparatus.

An OLED display apparatus is a spontaneous emission type display apparatus and is not only advantageous in terms of power consumption due to low voltage operation, but also excellent in color expression, response speed, viewing angle, and contrast ratio (CR). Such OLED display apparatuses are evolving from flat OLED display apparatuses to curved OLED display apparatuses.

A curved OLED display apparatus has a structure in which a back cover or cover bottom, an organic light emitting display panel, a polarizing plate, a touch sensor, and a cover member are laminated, and these components are joined by an adhesive member. For example, the curved OLED display apparatus has a structure in which an adhesive member is placed between a polarizing plate and a touch electrode to bond the polarizing plate and the touch electrode.

A curved OLED display apparatus is completed by forming a curved state of a flat OLED display panel using equipment or manually, and assembling the OLED display panel in the curved state and a curved back cover or cover bottom.

Therefore, a lot of investment, including equipment, is required to manufacture a curved OLED display apparatus, and since a flat OLED display panel is forcibly made curved, a lot of stress is applied to the OLED display panel itself due to the restoring force of the curved OLED display panel, and thus there is a possibility of various defects such as screen operation failure and cracks in the OLED display panel.

### SUMMARY

Accordingly, embodiments of the present disclosure are directed to a flexible curved display apparatus that substantially obviate one or more problems due to limitations and disadvantages of the related art.

An aspect of the present disclosure is to provide a flexible curved display apparatus with a curvature which is capable of being changed in various ways.

Another aspect of the present disclosure is to provide an optimized flexible curved display apparatus capable of reducing the stress of a display panel and the manufacturing cost.

Another aspect of the present disclosure is to provide a flexible curved display apparatus capable of preventing screen operation failure and display panel cracks due to the stress of the display panel.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described, as embodied and broadly described herein, a flexible curved display apparatus comprises a display part displaying an image, and a curvature-forming member having an inner side joined to a rear surface of the display part to bend the display part.

The curvature-forming member may include a plurality of body parts disposed in a row, a hinge member penetrating two adjacent body parts to connect the two adjacent body parts and forming a rotation axis of each body part of the two adjacent body parts, and a torsion spring whose both ends push the two adjacent body parts in a first direction in which the display part is located to offset a restoring force of the display part being bent.

Specific details of other embodiments are included in the detailed description and drawings.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles of the present disclosure. In the drawings:

FIG. 1 is a block diagram showing a display apparatus according to an embodiment of the present disclosure;

FIG. 2 is a circuit diagram showing a pixel circuit in the display apparatus according to an embodiment of the present disclosure;

FIG. 3 is a cross-sectional view showing the display apparatus according to the embodiment of the present disclosure;

FIG. 4 shows a flat state and a curved (or bent) state of a flexible curved display apparatus according to an embodiment of the present disclosure;

FIG. 5 is a configuration diagram of a curvature forming member 800 of the flexible curved display apparatus according to an embodiment of the present disclosure;

FIG. 6 is an enlarged view of a portion “A” of FIG. 5;

FIG. 7 is a specific configuration diagram of a torsion spring of FIG. 6;

FIG. 8 is an exploded perspective view of FIG. 6;

FIG. 9 is a specific exploded perspective view of each washer and side walls of one body part of FIG. 8;

FIG. 10 is a cross-sectional view along the line B-B′ in FIG. 6;

FIG. 11 is a diagram illustrating states of a torsion spring of the display apparatus according to an embodiment of the present disclosure;

FIG. 12 is a cross-sectional view of a body part and a cover of a display apparatus according to an embodiment of the present disclosure; and

FIG. 13 is a cross-sectional view of a body part and a cover of a display apparatus according to another embodiment of the present disclosure.

### DETAILED DESCRIPTION

Hereinafter, embodiments of the present disclosure will be described in detail with reference to the attached drawings.

In the following description, the component names used in the description below are selected for ease of writing of the present disclosure and may differ from the names of parts of the actual product.

The shapes, sizes, ratios, angles, numbers, and the like, which are illustrated in the drawings in order to describe various embodiments of the present disclosure, are merely given by way of example, and therefore, the present disclosure is not limited to the illustrations in the drawings. Throughout the present disclosure, the same reference numerals refer to substantially the same components.

In the following description, if a detailed description of known techniques associated with the present disclosure would unnecessarily obscure the gist of the present disclosure, detailed description thereof will be omitted

In the present disclosure, when the terms “comprise”, “include”, and the like are used, other elements may be added unless the term “only” is used. The singular forms are intended to include the plural forms as well, unless the context clearly indicates otherwise.

In interpretation of a component included in various embodiments of the present disclosure, the component is interpreted as including an error range unless otherwise explicitly described.

In describing various embodiments of the present disclosure, when describing a positional relationship, for example, when the positional relationship between two parts is described using “on”, “above”, “below”, “beside”, or the like, one or more other parts may be located between the two parts unless the term “directly” or “closely” is used.

In describing various embodiments of the present disclosure, when describing a temporal relationship, for example, when describing a temporal chronological relationship using the terms “after”, “following”, “next”, “before”, etc., cases that are not continuous may also be included unless “immediately” or “directly” is used.

In the description of the various embodiments of the present disclosure, although terms such as, for example, “first” and “second” may be used to describe various elements, these terms are merely used to distinguish the same or similar elements from each other. Therefore, in the present disclosure, an element modified (or defined) by “first” may be the same as an element modified (or defined) by “second” within the technical scope of the present disclosure unless otherwise mentioned.

Features within the various embodiments of the present disclosure may be partially or wholly combined, and may technically operate or operate in connection, and various embodiments may be implemented independently of each other or may be implemented in combination.

Hereinafter, a display apparatus according to an embodiment of the present disclosure will be described with reference to the drawings.

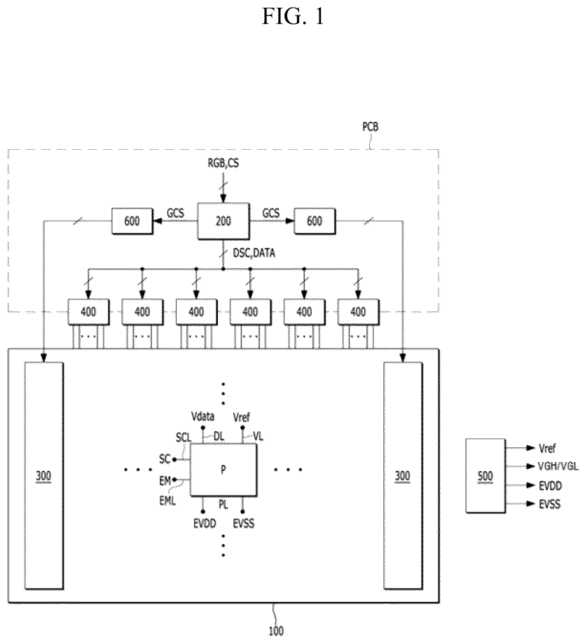

FIG. 1 is a block diagram showing a display apparatus according to an embodiment of the present disclosure.

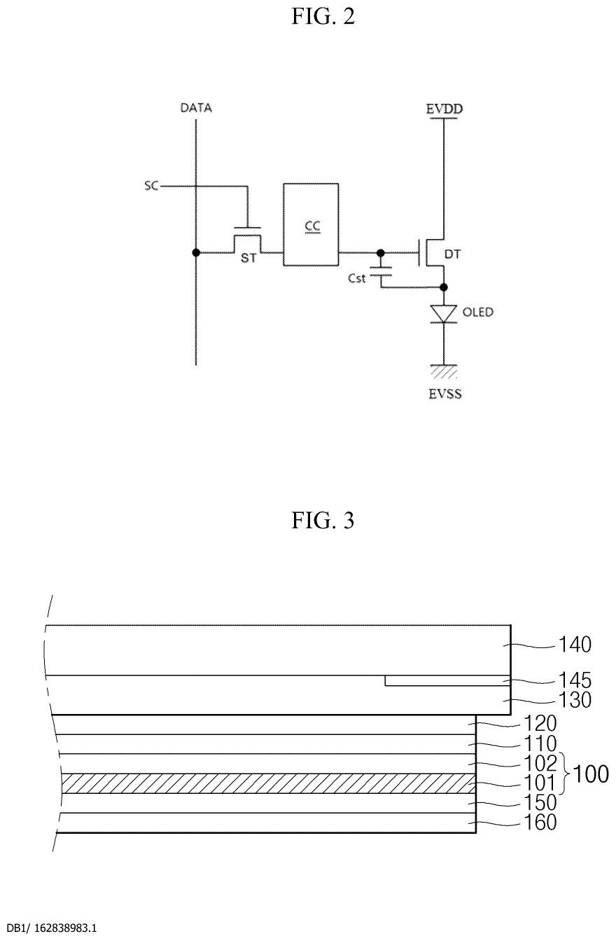

FIG. 2 is a circuit diagram of a pixel included in the display apparatus according to an embodiment of the present disclosure.

As illustrated in FIG. 1, a display apparatus according to an embodiment of the present disclosure includes a display panel 100 including a plurality of pixels P, a controller 200, a gate driving circuit 300 that supplies a gate signal to each of the plurality of pixels P, a data driving circuit 400 that supplies a data signal to each of the plurality of pixels P, a power supply 500 that supplies power required to drive each of the plurality of pixels P, a level shifter 600 that adjusts the level of a gate signal applied to the gate driving circuit 300, and a sensing unit (not illustrated in the drawing) that detects deterioration of the plurality of pixels P. Here, the controller 200, the gate driving circuit 300, the data driving circuit 400, and the sensing unit may be collectively referred to as a control unit.

The display panel 100 may include an active area (can also be referred to as a display area) in which the plurality of pixels P are positioned, and a non-active area (can also be referred to as a non-display area) disposed to surround the active area, in which the gate driving circuit 300 and the data driving circuit 400 are disposed. The gate driving circuit 300 may also be disposed in the active area.

In the display panel 100, a plurality of gate lines (for example, a scan line SCL and an emission control line EML) intersect a plurality of data lines DL, and the pixels P are connected to the gate lines (for example, the scan line SCL and the emission control line EML) and the data lines DL. Specifically, one pixel P receives a gate signal from the gate driving circuit 300 through the gate lines (for example, the scan line SCL and the emission control line EML), receives a data signal from the data driving circuit 400 through a data line DL, and receives a high-level driving voltage EVDD and a low-level driving voltage EVSS from the power supply 500 through a driving voltage line PL.

Here, a scan signal SC and an emission control signal EM are supplied through the gate lines (for example, the scan line SCL and the emission control line EML), and a data voltage Vdata is supplied through the data lines DL. In addition, according to various embodiments, the gate lines (for example, the scan line SCL and the emission control line EML) may include a plurality of scan lines SCL through which the scan signal SC is supplied and an emission control line EML through which the emission control signal EM is supplied. In addition, the plurality of pixels P may additionally include a power line VL to receive a reference voltage Vref and an initialization voltage.

TFTs (that is, Thin Film Transistors) constituting each pixel P may be implemented as oxide TFTs including an oxide semiconductor layer. The oxide TFT may be advantageous for a large-area display panel 100 when considering electron mobility, process deviation, etc. The present disclosure is not limited thereto, and a semiconductor layer of a TFT may be formed of amorphous silicon, polysilicon, or the like.

In addition, each pixel P includes a light-emitting element and a pixel circuit that controls operation of the light-emitting element. Here, the light-emitting element may be composed of an anode, a cathode, and an emission layer provided between the anode and the cathode.

Each pixel P may include a switching transistor ST, a driving transistor DT, a compensation circuit CC, a light-emitting element OLED, and a storage capacitor Cst, as illustrated in FIG. 2.

The light-emitting element OLED may operate to emit light according to a driving current formed by the driving transistor DT.

The switching transistor ST may perform a switching operation such that a data signal DATA supplied through a data line DL is stored as a data voltage in the storage capacitor Cst in response to a scan signal SC supplied through a scan line SCL. The storage capacitor Cst may maintain the data voltage for one frame.

The driving transistor DT may operate to allow a constant driving current to flow between the high-level power line EVDD and the low-level power line EVSS in response to the data voltage stored in the storage capacitor Cst.

The compensation circuit CC is a circuit for compensating for the threshold voltage of the driving transistor DT, and the compensation circuit CC may include one or more thin film transistors and a capacitor. The configuration of the compensation circuit CC may vary depending on the compensation method.

For example, the pixel P illustrated in FIG. 2 is configured as a 2T (Transistor) 1C (Capacitor) structure including the switching transistor ST, the driving transistor DT, the storage capacitor Cst, and the light-emitting element OLED, but if the compensation circuit CC is added, the pixel P may be configured in various structures such as 3T1C, 4T2C, 5T2C, 6T1C, 6T2C, 7T1C, 7T2C, and 8T1C.

The display panel 100 may be implemented as a non-transparent display panel or a transparent display panel. The transparent display panel may be applied to a transparent display apparatus in which an image is displayed on the screen and the actual background is visible. The display panel 100 may be manufactured as a flexible display panel. The flexible display panel may be implemented as an organic light emitting display panel using a plastic substrate.

The plurality of pixels P may be divided into a red pixel, a green pixel, and a blue pixel for color implementation (or, in some cases, each pixel P may comprise a red sub-pixel, a green sub-pixel, and a blue sub-pixel). The plurality of pixels P may further include a white pixel. Each pixel P includes a pixel circuit.

Touch sensors may be provided on the display panel 100. Touch input may be sensed using separate touch sensors or may be sensed through the pixels P. The touch sensors may be implemented as on-cell type or add on type touch sensors disposed on the screen of the display panel 100 or as in-cell type touch sensors built into the display panel 100.

The controller 200 processes image data RGB input from the outside such that the image data RGB is suitable for the size and resolution of the display panel 100 and supplies the same to the data driving circuit 400. The controller 200 generates a gate control signal GCS and a data control signal DCS using timing signals CS input from the outside, such as a dot clock signal CLK, a data enable signal DE, a horizontal synchronization signal Hsync, and a vertical synchronization signal Vsync. By supplying the generated gate control signal GCS and data control signal DCS to the gate driving circuit 300 and the data driving circuit 400, the controller 200 controls the gate driving circuit 300 and the data driving circuit 400.

The controller 200 may be configured to be combined with various processors, such as a microprocessor, a mobile processor, and an application processor depending on the device to be mounted in the display apparatus.

A host system may be any one of a TV system, a set-top box, a navigation system, a personal computer (PC), a home theater system, a mobile device, a wearable device, and a vehicle system.

The controller 200 may multiply an input frame frequency by i and control the operation timing of a display panel driver at a frame frequency of input frame frequency×i (i being a positive integer greater than 0) Hz. The input frame frequency may be 60 Hz in the case of NTSC (National Television Standards Committee) and 50 Hz in the case of PAL (Phase-Alternating Line).

The controller 200 generates signals such that the pixels P can be driven at various refresh rates. That is, the controller 200 generates signals related to driving such that the pixels P can be driven in a variable refresh rate (VRR) mode or can switch between a first refresh rate and a second refresh rate. For example, the controller 200 may drive the pixels P at various refresh rates by simply changing the rate of the clock signal, generating synchronization signals such that a horizontal blank or a vertical blank is created, or driving the gate driving circuit 300 in a mask manner.

The controller 200 generates the gate control signal GCS for controlling the operation timing of the gate driving circuit 300 and the data control signal DSC for controlling the operation timing of the data driving circuit 400 on the basis of a timing signal CS received from the host system. The controller 200 controls the operation timing of the display panel driver to synchronize the gate driving circuit 300 and the data driving circuit 400.

The data driving circuit 400 receives image data DATA and the data control signal DCS from the controller 200. In response to the data control signal DCS from the controller 200, the data driving circuit 400 converts the image data DATA into a gamma compensation voltage to generate a data voltage Vdata, and supplies the data voltage Vdata to the data lines DL of the display panel 100 in synchronization with a scan signal SC. The data driving circuit 400 may be connected to the data lines of the display panel 100 by a COG (Chip On Glass) process or a TAB (Tape Automated Bonding) process.

The gate driving circuit 300 operates according to the gate control signal GCS input from the level shifter 600 to generate a gate signal. Then, the gate signal is sequentially supplied to the gate lines GL. The gate driving circuit 300 may be formed directly on a lower substrate of the display panel 100 in a GIP (Gate driver In Panel) structure. The gate driving circuit 300 may be formed in an active area in which a screen (or image)is displayed on the display panel 100, or may be formed in a non-active area outside the active area. The non-active area may include a bezel area, or may be the same as the bezel area. In the GIP structure, the level shifter 600 may be mounted on a printed circuit board (PCB) along with the controller 200.

The power supply 500 generates DC power required to drive the pixel array of the display panel 100 and the display panel driver using a DC-DC converter. The DC-DC converter may include a charge pump, a regulator, a buck converter, a boost converter, etc. The power supply 500 may receive a DC input voltage applied from the host system (not shown) and generate DC voltages such as gate-on voltages VGL and VEL, gate-off voltages VGH and VEH, the high-level driving voltage EVDD, and the low-level driving voltage EVSS. The gate-on voltages VGL and VEL and the gate-off voltages VGH and VEH are supplied to the level shifter and the gate driving circuit 300. The high-level driving voltage EVDD and the low-level driving voltage EVSS are supplied commonly to the pixels P.

The level shifter 600 boosts a TTL (Transistor-Transistor-Logic) level voltage of the gate control signal GCS input from the controller 200 to the gate high voltage VGH and the gate low voltage VGL that can drive TFTs formed in the display panel 100 and supplies the boosted voltages to the gate driving circuit 300. The gate control signal GCS may include a start signal and a clock signal. The plurality of pixels P of the display panel 100 may include at least a first pixel, a second pixel, and a third pixel. The first pixel, the second pixel, and the third pixel may emit light of different colors. For example, the first pixel may be a red pixel, the second pixel may be a green pixel, and the third pixel may be a blue pixel.

The plurality of pixels P may have the same size or different sizes. The first pixel, the second pixel, and the third pixel may be designed to have different sizes in consideration of the lifespan of the light-emitting element OLED included in each of the first pixel, the second pixel, and the third pixel, color balance, or the like.

FIG. 3 is a cross-sectional view showing a display apparatus according to an embodiment of the present disclosure.

As shown in FIG. 3, in the display apparatus, an array layer 102 including a thin film transistor, a light-emitting element, and an encapsulation unit may be disposed on a substrate 101, and a polarizing layer 110 may be disposed on the array layer 102. The substrate 101 and the array layer 102 disposed on the substrate 101 may be referred to as a display panel 100.

A back plate 150 may be disposed on a rear side of the substrate 101, and a metal plate 160 may be disposed on a rear side of the back plate 150.

Further, a black matrix 145 may be disposed on a rear surface of a cover glass 140 of a non-active area, and a touch sensor layer 130 may be disposed on the rear side of the cover glass 140.

The cover glass 140 on which the touch sensor layer 130 is disposed, and the substrate 101 on which the array layer 102, the polarizing layer 110, the back plate 150, and the metal plate 160 are disposed are bonded using a transparent adhesive material (OCA; 120). That is, the touch sensor layer 130 and the polarizing layer 110 are bonded by the transparent adhesive material 120.

When the touch sensor layer 130 and the polarizing layer 110 are bonded by the transparent adhesive material 120, bubbles may be generated due to non-bonding at corners of the display apparatus due to irregularity of the touch sensor layer 130. In addition, due to the fluidity of the transparent adhesive material 120, the transparent adhesive material may protrude outward due to the force applied during bonding.

The present disclosure can provide the transparent adhesive material 120 that prevents the occurrence of bubbles between the touch sensor layer 130 and the transparent adhesive material 120 in a corner area of the display apparatus and prevent the transparent adhesive material 120 from protruding outward.

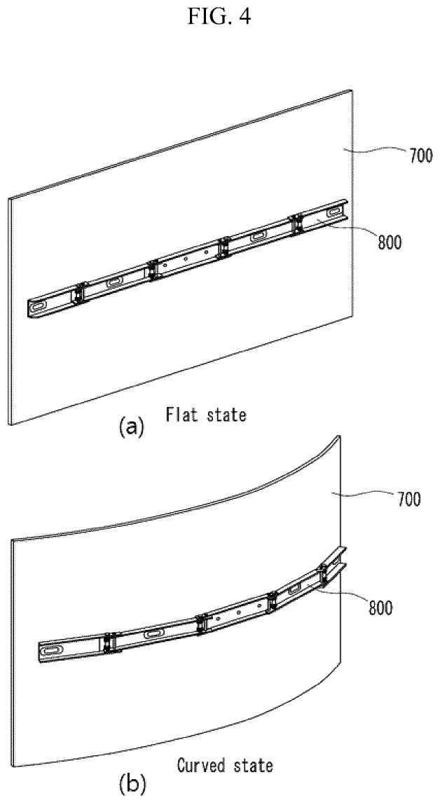

FIG. 4 shows a flat state and a curved state of a flexible curved display apparatus according to an embodiment of the present disclosure, wherein (a) of FIG. 4 shows a flat state, and (b) of FIG. 4 shows a curved state.

A flexible curved display apparatus according to an embodiment of the present disclosure may include a display part 700 and a curvature-forming member 800, as illustrated in FIG. 4. The display part 700 may include a display panel 100 illustrated in FIG. 1 to FIG. 3 and a frame for supporting the display panel 100 and can display images through the display panel 100. The curvature-forming member 800 has an inner side (or inner surface) joined (or coupled) to the rear surface of the display part 700 (for example, by means of an adhesive material, but not limited thereto) and can serve to bend the display part 700.

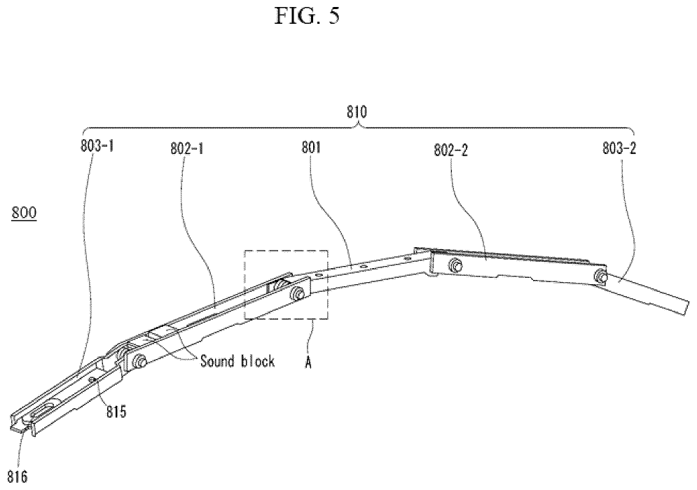

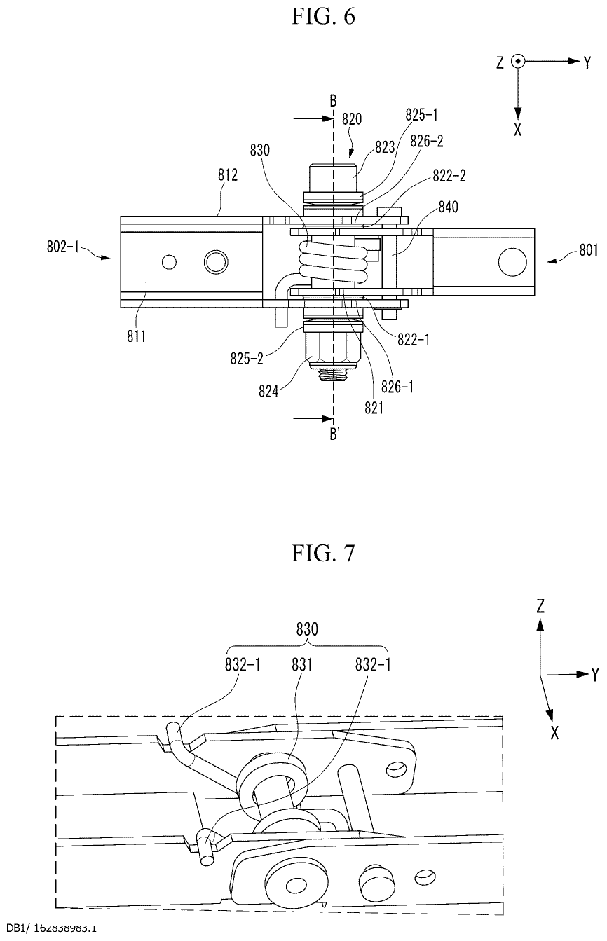

FIG. 5 is a configuration diagram of the curvature-forming member 800 of the flexible curved display apparatus according to an embodiment of the present disclosure. FIG. 6 is an enlarged view of a portion “A” of FIG. 5. FIG. 7 is a specific configuration diagram of a torsion spring of FIG. 6.

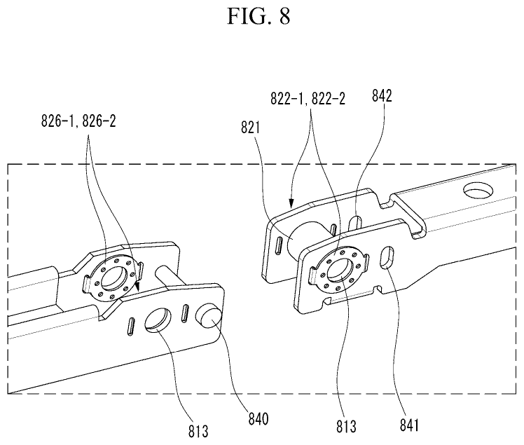

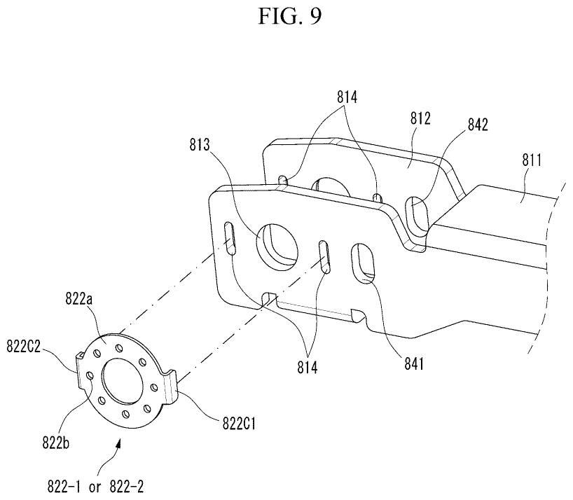

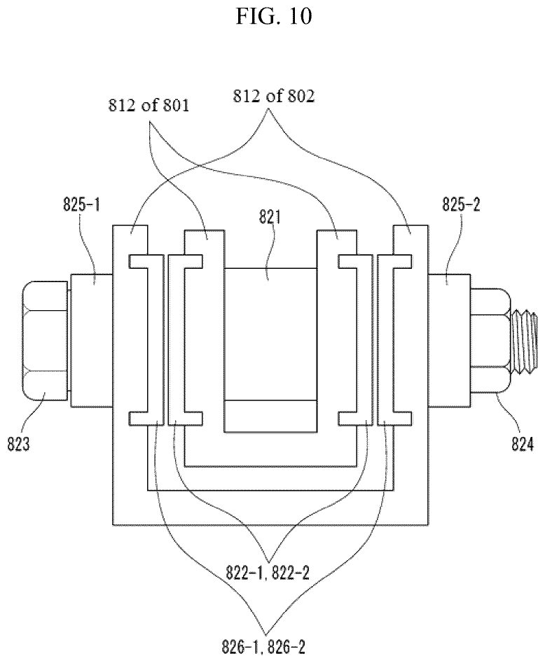

FIG. 8 is an exploded perspective view of FIG. 6. FIG. 9 is a detailed exploded perspective view of each washer and side walls of one body part of FIG. 8. FIG. 10 is a cross-sectional view along the line B-B′ of FIG. 6.

As illustrated in FIGS. 5-6, the curvature-forming member 800 may include a plurality of body parts 810 (here, the plurality of body parts are collectively assigned with a reference numeral of “810”) disposed in a row, a hinge member 820 that penetrates adjacent body parts to connect the adjacent body parts and forms a rotation axis of each body part of the adjacent body parts, and a torsion spring 830 having both ends that push the adjacent body parts in a first direction in which the display part 700 is located to offset the restoring force of the display part 700 in a curved (or bent) state.

The plurality of body parts 810 may include a first body part 801 positioned at the center, second body parts 802-1 and 802-2 disposed at both ends of the first body part 801, and third body parts 803-1 and 803-2 disposed at the outer ends (that is, the ends away from the first body part 801) of the second body parts 802-1 and 802-2. Although FIG. 5 illustrates that the plurality of body parts 810 includes the first body part 801, two second body parts 802-1 and 802-2, and two third body parts 803-1 and 803-2, the present disclosure is not limited thereto. For example, the plurality of body parts 810 may further include a pair of body parts disposed at the outer ends of the third body parts 803-1 and 803-2, and so on. Generally speaking, the plurality of body parts may include a first body part positioned at the center, and second to N-th body parts sequentially disposed at both ends of the first body part, and here, N may be a natural number of 3 or more. Here, based on the body part positioned at the center, odd-numbered body parts and even-numbered body parts can be rotatably connected by the hinge member 820.

Each of the first to third body parts 801, 802-1, 802-2, 803-1, and 803-2 of the plurality of body parts 810 may include a body 811 facing the display part 700 and extending in a second direction different from the first direction, and side walls 812 extending vertically from the body 811, as illustrated in FIG. 6 to FIG. 8. The side walls 812 may extend farther in the second direction than the body 811 and may include a hinge hole 813 through which the hinge member 820 passes. For example, the side walls 812 of the outmost body part may extend farther in the second direction than the body 811 on both sides of the body 811 at one end (or in one direction) of the body 811. In addition, the side walls 812 of body parts other than the outmost body part may extend farther in the second direction than the body 811 on both sides of the body 811 at both ends (or in both directions) of the body 811. Accordingly, the outmost body part may have two side walls 812, and the body parts other than the outmost body part may have four side walls 812.

For example, the four side walls 812 of the first body part 801 may be disposed inside the four side walls 812 of the second body parts 802-1 and 802-2, and the two side walls 812 of each of the third body parts 803-1 and 803-2 may be disposed inside the four walls 812 of the second body parts 802-1 and 802-2. For example, when the plurality of body parts 810 includes N pairs of body parts, based on the body part disposed at the center, the side walls 812 of odd-numbered body parts 801, 803-1, and 803-2 may be disposed inside the side walls 812 of even-numbered body parts 802-1 and 802-2. For example, the width between two parallel and adjacent side walls 812 of the first body part 801 may be less than the width between two parallel and adjacent side walls 812 of the second body parts 802-1 and 802-2. In addition, the width between two parallel and adjacent side walls 812 of the third body parts 803-1 and 803-2 may be less than the width between two parallel and adjacent side walls 812 of the second body parts 802-1 and 802-2.

On the other hand, when the plurality of body parts 810 includes N pairs of body parts, the side walls 812 of the even-numbered body parts 802-1 and 802-2 may be disposed inside the side walls 812 of the odd-numbered body parts 801, 803-1, and 803-2 based on the body part disposed at the center. For example, the width between two parallel and adjacent side walls 812 of the second body parts 802-1 and 802-2 may be less than the width between two parallel and adjacent side walls 812 of the first and third body parts 801, 803-1 and 803-2.

As illustrated in FIG. 6 to FIG. 9, the hinge member 820 may include a support member 821 that is positioned between the side walls 812 of one of two adjacent body parts among the first to third body parts 801, 802-1, 802-2, 803-1, and 803-2 and supports the side walls 812 of one of the two adjacent body parts among the first to third body parts 801, 802-1, 802-2, 803-1, and 803-2, two first washers 822-1 and 822-2 that are positioned on the outer sides of the side walls 812 of one of the two adjacent body parts among the first to third body parts 801, 802-1, 802-2, 803-1, and 803-2, two second washers 826-1 and 826-2 that are positioned on the inner sides of the side walls 812 of the other one of the two adjacent body parts among the first to third body parts 801, 802-1, 802-2, 803-1, and 803-2, a hinge hole 813 formed in the side walls 812 of each of the two adjacent body parts among the first to third body parts 801, 802-1, 802-2, 803-1, and 803-2, a bolt 823 penetrating the support member 821 and the first and second washers 822-1, 822-2, 826-1, and 826-2, and a nut 824 fastened to the bolt 823 to apply a compressive force to the side walls 812 of the two adjacent body parts among the first to third body parts 801, 802-1, 802-2, 803-1, and 803-2, the support member 821, and the first and second washers 822-1, 822-2, 826-1, and 826-2. Here, the first washer 822-1 and the second washer 826-1 may be disposed to be in contact with each other, and the first washer 822-2 and the second washer 826-2 may be disposed to be in contact with each other.

As illustrated in FIG. 9, each of the first and second washers 822-1, 822-2, 826-1, and 826-2 may include a ring-shaped washer body 822a, washer protrusions 822c1 and 822c2 protruding from both sides of the washer body 822a, and a plurality of lubricant receiving holes 822b formed in the washer body 822a to allow a lubricant such as grease to be introduced therethrough without leaking.

With this configuration, there is no friction between the sides of two adjacent body parts, and friction can occur between the first washers 822-1 and 822-2 and the second washers 826-1 and 826-2. Therefore, the material of each body part can be diversified, and the wear (or friction) area can be minimized. In addition, since the first and second washers 822-1, 822-2, 826-1, and 826-2 can be manufactured to be used in a fitting manner, they can be easily replaced. Further, by using lubricant such as grease between the first washers 822-1 and 822-2 and the second washers 826-1 and 826-2, the surface roughness and the coefficient of friction can be managed, and the bending force can be reduced and stabilized.

The side walls 812 of the first to third body parts 801, 802-1, 802-2, 803-1, and 803-2 may further include washer holes 814 for receiving the washer protrusions 822c1 and 822c2 of the first and second washers 822-1, 822-2, 826-1, and 8226-2.

In addition, the hinge member 820 may further include disc springs 825-1 and 825-2 that are positioned between the bolt 823 and a side wall 812 of one of two adjacent body parts among the first to third body parts 801, 802-1, 802-2, 803-1, and 803-2 and between the nut 824 and a side wall 812 of the other of the two adjacent body parts among the first to third body parts 801, 802-1, 802-2, 803-1, and 803-2 to compensate for a tightening torque due to loosening of the bolt 823 and the nut 824. Accordingly, a ratchet structure, a locking structure, and a friction brake are applied to the hinge member 320, and thus fine angle adjustment is possible.

Each of the first to third body parts 801, 802-1, 802-2, 803-1, and 803-2 may include a cover hole 815 and a display hole 816 which will be described later. In addition, at least one of the first to third body parts 801, 802-1, 802-2, 803-1, and 803-2 may be provided with a sound block that indicates that the body part has reached a flat state or a curved state.

The torsion spring 830 includes, as shown in FIG. 6 and FIG. 7, a coil portion 831 that accommodates the support member 821 of the hinge member 820, and first and second extension portions 832-1 and 832-2 that extend from both ends of the coil portion 831 and are fastened to the outer sides of the side walls 812 of one of two adjacent body parts among the first to third body parts 801, 802-1, 802-2, 803-1, and 803-2 where the support member 821 of the hinge member 820 is not disposed, and the first and second extension portions 832-1 and 832-2 can serve to push each body part in the first direction. For example, the curvature of the display part 700 may be determined according to the angle formed by adjacent body parts. In addition, the torque of the torsion spring, the force of tightening the bolt 823 and nut 824 of the hinge member 820, and the holding force of material friction are equivalent to the reaction force according to the curvature of the display part 700, and thus a desired curved state can be maintained.

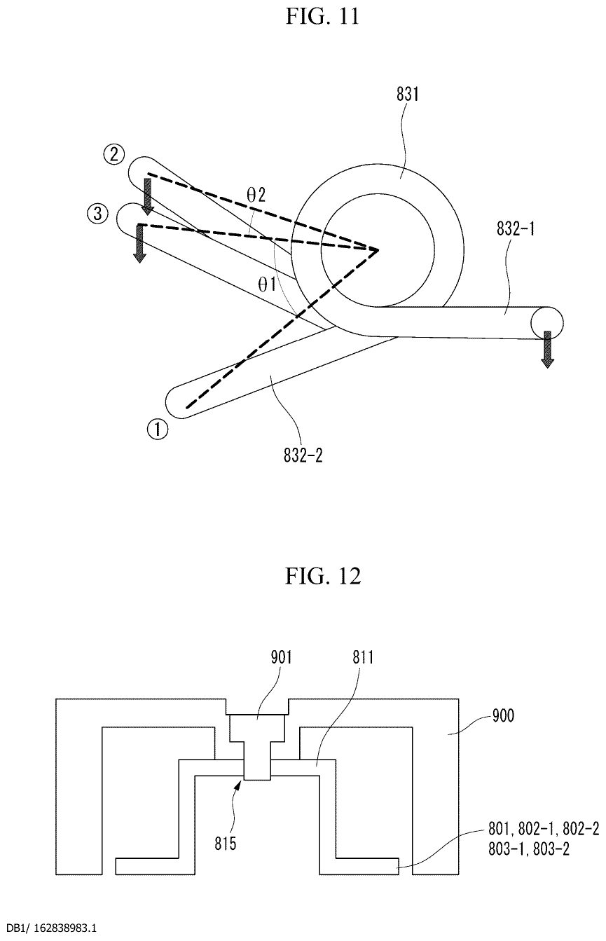

FIG. 11 is a diagram illustrating states of the torsion spring 830 of the display apparatus according to an embodiment of the present disclosure.

In FIG. 11, \textcircled{1} shows the initial state of the torsion spring 830, \textcircled{2} shows the torsion spring 830 coupled to the curvature-forming member 800 in a flat state, and \textcircled{3} shows the torsion spring 830 coupled to the curvature-forming member 800 in a bent state. The torsion spring 830 has a property of returning to the initial state, and thus the torsion spring 830 in the states \textcircled{2} and \textcircled{3} has a force (downward arrow in the drawing) to return to state \textcircled{1}. The display part 700 is coupled to the inner surfaces of the bodies 811 of the plurality of body parts 810, and the first and second extension portions 832-1 and 832-2 are disposed on the outer surfaces of the bodies 811 of adjacent body parts, and thus the first and second extension portions 832-1 and 832-2 of the torsion spring 830 can push the adjacent body parts in the direction (first direction) in which the display part 700 is located (or placed).

The angle formed by the adjacent body parts can be maintained by the hinge member 820. Tightening of the bolt 823 and the nut 824 of the hinge member 820 and the frictional force between the first and second washers 822-1 and 822-2 can form a holding force that maintains a desired curved state.

In addition to the holding force of the hinge member 820, the spring force of the torsional spring 830 and the restoring force according to the curvature of the curved display part may be additionally applied to the curvature-forming member 800. At this time, as described above, the spring force of the torsion spring 830 pushes the plurality of body parts 810 in the first direction (the direction in which the display part is located or placed), and the restoring force of the display part 700 pushes the plurality of body parts 810 in a direction opposite to the first direction. That is, the spring force of the torsion spring 830 and the restoring force of the display part 700 are opposing forces.

When the curvature-forming member 800 is in a flat state or stationary in a curved state, static friction force may be applied. In this case, the spring force of the torsion spring 830 and the restoring force of the display part 700 may be smaller than the static friction force and thus may not have a significant effect.

On the other hand, when the curvature-forming member 800 is bent or straightened, kinetic friction force smaller than the static friction force is applied, and in this case, the spring force of the torsion spring 830 and the restoring force of the display part 700 may affect the operation of the curvature-forming member 800.

When the curvature-forming member 800 is bent, the bending force with which the curvature-forming member 800 is bent may have a value obtained by subtracting the spring force from the sum of the holding force of the hinge member 820 and the restoring force of the display part 700. That is, when the curvature-forming member is bent, the spring force can aid in bending of the curvature-forming member by offsetting the restoring force of the display part.

On the other hand, when the curvature-forming member 800 is straightened, the bending force for unfolding the curvature-forming member 800 may be a value obtained by subtracting the restoring force of the display part 700 from the sum of the holding force of the hinge member 820 and the spring force of the torsion spring 830.

The curvature-forming member 800 may further include a guide pin 840 that is disposed at a predetermined distance from the hinge member 820 in the longitudinal direction of the curvature-forming member 800, as illustrated in FIG. 6 to FIG. 8. For example, two first guide holes 841 may be formed in the side walls 812 of one of two adjacent body parts among the first to third body parts 801, 802-1, 802-2, 803-1, and 803-2 on which the support member 821 of the hinge member 820 is disposed, further inward than the hinge hole 813, two second guide holes 842 may be formed in the side walls 812 of the other of the two adjacent body parts among the first to third body parts 801, 802-1, 802-2, 803-1, and 803-2 on which the support member 821 of the hinge member 820 is not disposed, further outward than the hinge hole 813, and the guide pin 840 may penetrate the first guide holes 841 and the second guide holes 842 to be fastened thereto.

One of the first and second guide holes 841 and 842 may have a shape corresponding to the cross-sectional shape of the guide pin 840 to fix the guide pin 840. The other of the first and second guide holes 841 and 842 may have a shape in which the guide pin 840 can move along an arc having a predetermined central angle with respect to the rotation axis. When an adjacent body part rotates with respect to the hinge member 820, and the guide pin 840 located at a predetermined distance from the hinge member 820 also rotates with respect to the hinge member 820. At this time, since the guide pin 840 can move only within the guide hole having a predetermined central angle, the movement range of the guide pin 840 is limited to within the predetermined central angle. That is, the first and second guide holes 841 and 842 having a predetermined central angle and the guide pin 840 limit the range within which adjacent body parts can rotate. This determines the limit of movement of the guide pin 840, thereby limiting the angle that can be formed by adjacent body parts.

FIG. 12 is a cross-sectional view of a body and a cover of a display apparatus (in other words, a flexible curved display apparatus) according to an embodiment of the present disclosure.

The flexible curved display apparatus may include a cover 900 covering the curvature-forming member 800.

The cover 900 may be formed of a rigid body to protect the curvature-forming member 800 and transmit a force for bending the curvature-forming member 800 to the curvature-forming member 800.

Since the cover 900 needs to be bent together in response to the curvature of the display part 700 and the curvature-forming member 800, a plurality of covers 900 may be configured to be mounted on the first to third body parts 801, 802-1, 802-2, 803-1, and 803-2 instead of one cover 900 covering the curvature-forming member 800. The number of covers 900 may be the same as the number of body parts constituting the curvature-forming member 800, and the body 811 of each of the plurality of body parts may include a cover hole 815 for coupling with the cover 900 (refer to FIG. 5). Each cover 900 may be fixed to one body part through coupling using the cover hole 815 and a bolt 901.

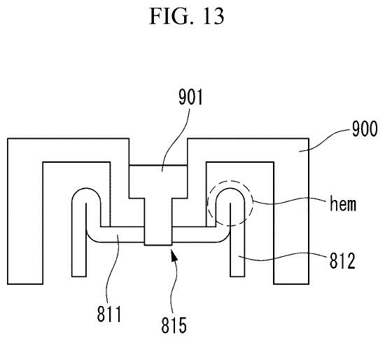

FIG. 13 is a cross-sectional view of a body and a cover of a display apparatus according to another embodiment of the present disclosure.

To achieve a slim display apparatus and reduce the sizes of parts, it is desirable to reduce the height and width of the cover. Accordingly, the design specifications of the cover 900, such as the height and width, may be determined depending on the design specifications of each body part. In the display apparatus of another embodiment of the present disclosure, as shown in FIG. 13, the size of the cover 900 can be reduced by forming a hem structure between the body 811 and the side wall 812 of the body part.

For example, as shown in FIG. 13, the cross-sectional shape of each body part may include a hem structure. The body 811 of each of the first to third body parts 801, 802-1, 802-2, 803-1, and 803-2 may not be connected to the uppermost part of the side wall 812 and may be positioned at the middle height of the side wall 812 due to the hem structure. As the height of the body 811 decreases, the height of the cover 900 coupled with the body 811 can also decrease.

In addition, the body 811 of each body part may include a display hole 816 for coupling with the display part 700 (refer to FIG. 5). The coupling position of the display part 700 and each body part may move horizontally according to change from a flat state to a curved state. Therefore, the display hole 816 may have a length extending in the horizontal direction. By forming the display hole 816 in the body 811 instead of an extension part that extends from the body part, the width of the body part can be prevented from increasing, and accordingly, the width of the cover 900 can be prevented from increasing.

According to the present disclosure, since a curvature-forming member is applied, a curved display panel (and thus a curved display apparatus) can be implemented without risk of breakage.

According to the present disclosure, a curved state of the display panel can be stably implemented with a plurality of body parts having a hinge member that forms a torque equivalent to the restoring force of the display panel.

According to the present disclosure, various curvatures can be achieved by adjusting rotation angles of the hinge member and the body parts.

According to the present disclosure, the risk of cracks and screen operation failure of the display panel can be reduced by decreasing the stress applied to the display panel, and thus a smaller curvature can be achieved.

According to the present disclosure, it is possible to simplify equipment in the manufacturing process, thereby reducing manufacturing difficulty and manufacturing costs.

The effects according to the embodiments are not limited to the effects described above, and more diverse effects are included in the present disclosure.

It will be apparent to those skilled in the art that various modifications and variations can be made in the flexible curved display apparatus of the present disclosure without departing from the technical idea or scope of the disclosure. Thus, it is intended that the present disclosure cover the modifications and variations of this disclosure provided they come within the scope of the appended claims and their equivalents.

What is claimed is:

1. A flexible curved display apparatus, comprising:
a display part displaying an image; and
a curvature-forming member having an inner side joined to a rear surface of the display part to bend the display part,
wherein the curvature-forming member comprises:
a plurality of body parts disposed in a row;
a hinge member penetrating two adjacent body parts to connect the two adjacent body parts and forming a rotation axis of each body part of the two adjacent body parts; and
a torsion spring whose both ends push the two adjacent body parts in a first direction in which the display part is located to offset a restoring force of the display part being bent.

2. The flexible curved display apparatus of claim 1, wherein the plurality of body parts includes a first body part positioned at the center, and second to N-th body parts sequentially disposed at both ends of the first body part, N being a natural number of 3 or more,
wherein each body part is joined to an adjacent body part and can rotate with respect to the hinge member.

3. The flexible curved display apparatus of claim 2, wherein each of the plurality of body parts includes a body facing the display part and extending in a second direction different from the first direction, and two side walls extending vertically from the body,
wherein each side wall extends from the body in the second direction at at least one end of the body and includes a hinge hole through which the hinge member penetrates.

4. The flexible curved display apparatus of claim 3, further comprising a cover coupled to the outer surface of each of the plurality of body parts and accommodating the curvature-forming member.

5. The flexible curved display apparatus of claim 4, wherein the body of each of the plurality of body parts further includes a display hole for coupling with the display part, and a cover hole for coupling with the cover.

6. The flexible curved display apparatus of claim 4, wherein a hem structure is formed between the body and the side walls.

7. The flexible curved display apparatus of claim 3, wherein the side walls of odd-numbered body parts are disposed inside the side walls of even-numbered body parts based on the first body part located at the center.

8. The flexible curved display apparatus of claim 7, wherein a width between the side walls of the odd-numbered body parts is less than a width between the side walls of the even-numbered body parts.

9. The flexible curved display apparatus of claim 7, wherein the hinge member comprises:
a support member disposed between the side walls of the odd-numbered body parts to support the side walls of the odd-numbered body parts;
a plurality of washers disposed between the side walls of each body part;
a bolt penetrating a hinge hole formed in the side walls of each body part, the support member, and the plurality of washers; and
a nut fastened to the bolt and applying a compressive force to the side walls of two adjacent body parts, the support member, and the plurality of washers.

10. The flexible curved display apparatus of claim 9, wherein the plurality of washers includes two first washers disposed on the outer sides of the side walls of the odd-numbered body parts, and two second washers disposed on the inner sides of the side walls of the even-numbered body parts.

11. The flexible curved display apparatus of claim 9, wherein each washer includes a ring-shaped washer body, washer protrusions protruding from both sides of the washer body, and a plurality of lubricant receiving holes formed in the washer body to allow lubricant to be introduced without leaking.

12. The flexible curved display apparatus of claim 11, wherein each side wall of each body part further includes a washer hole in which the washer protrusions are received.

13. The flexible curved display apparatus of claim 9, wherein the hinge member further includes a disc spring disposed between the bolt and the side walls of the even-numbered body parts and between the nut and the side walls of the even-numbered body parts to compensate for a tightening torque due to loosening of the bolt and the nut.

14. The flexible curved display apparatus of claim 9, wherein the torsion spring includes a coil portion accommodating the support member of the hinge member, and first and second extension portions extending from both ends of the coil portion and fastened to the outer sides of the side walls of a body part of two adjacent body parts on which the support member is not disposed,
wherein the first and second extension portions serve to push each body part in the first direction.

15. The flexible curved display apparatus of claim 3, wherein the curve-forming member further comprises:
a guide pin disposed at a predetermined distance from the hinge member in a longitudinal direction of the curve-forming member,
two first guide holes formed in the side walls of one of two adjacent body parts on which the support member of the hinge member is disposed and positioned further inward than the hinge hole; and
two second guide holes formed in the side walls of the other of the two adjacent body parts on which the support member of the hinge member is not disposed and positioned further outward than the hinge hole,
wherein the guide pin penetrates the first guide holes and the second guide holes to be fastened to the first guide holes and the second guide holes.

16. The flexible curved display apparatus of claim 15, wherein the first guide holes have a shape in which the guide pin moves along an arc having a predetermined central angle with respect to the rotation axis.
